(19) United States
(12) Patent Application Publication
(10) Pub. No.: US 2008/0078056 A1
(43) Pub. Date: Apr. 3, 2008

(54) SWIVEL HINGE ASSEMBLY FOR PORTABLE ELECTRONIC DEVICE

(75) Inventors: SHENG-CHENG HSU, Tu-Cheng (TW); PU LUO, Shenzhen (CN); FAN-MING MENG, Shenzhen (CN); JIN-BU CAI, Shenzhen (CN)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: HON HAI PRECISION INDUSTRY CO., LTD., Tu-Cheng (TW)

(21) Appl. No.: 11/741,746

(22) Filed: Apr. 29, 2007

(30) Foreign Application Priority Data
Sep. 28, 2006 (CN) 200610200938.3

(51) Int. Cl. H05K 7/00

(52) U.S. Cl. 16/280

(57) ABSTRACT

An exemplary swivel hinge assembly (100) includes a main body (12), a pivot mechanism (16) and a swivel mechanism (15). The swivel mechanism includes a rotatable member (182), a fixing member (184), two bearing balls (185), an elastic piece (186), and a second pivot shaft (189). The rotatable member defines two first bearing grooves (1820). The fixing member defines two second bearing grooves corresponding to the first grooves. The bearing balls are disposed between the rotatable member and the fixing member, and are partly received in the second bearing grooves. The elastic piece is mounted on the main body, elastically resisting the fixing member. The second pivot shaft extends through the main body, the elastic piece, the fixing member, and the rotatable member, and is rotatable relative to the elastic piece, the main body, and the fixing member.

### BACKGROUND OF THE INVENTION

1. Field of the Invention

The present invention relates, generally, to swivel hinges, and more particularly to a swivel hinge assembly used in folding portable electronic devices.

2. Discussion of the Related Art

Generally, portable wireless devices allow users to communicate wirelessly. device Such portable wireless devices are classified into bar-type, flip-type, and folder-type devices according to the external appearance. The bar-type device includes a single housing having a bar-shape. The flip-type device includes a flip rotatably coupled to a bar-type housing by means of a hinge device. The flip generally has two functions, one function is to be closed to the housing for protecting a keypad or a display on the bar-type housing, and the other function is to be opened relative to the housing to be a microphone. The folder-type device includes a cover rotatably and foldably coupled to a single bar-type housing by means of a hinge device. The cover generally includes at least one display, and the display of the cover can be covered by a keypad on the bar-type housing when the cover is closed to the bar-type housing, thus the display of the cover and the keypad are protected by each other.

The above-mentioned portable wireless devices are well known to those skilled in the art, and typically include an antenna device, a data input/output device, and a data transmitting/receiving device. Generally, a keypad, allowing a user to input data by pushing the keys with his/her fingers, is mainly used as a data input device for wireless devices. A touch pad or a touch screen also can be used as a data input/output device. In addition, an LCD (Liquid Crystal Display) is mainly used as a data output device, i.e. a display.

Recently, users' demand for portable wireless devices have become diversified. However, although various kinds of additional devices, such as cameras or camcorders, have been added to portable wireless devices, the display for data output is usually rotated around only one axis in such a portable wireless device. That is, the display is usually only tiltable about a transverse pivot. When photographing an object or video communicating with a user at another device, the portable wireless device is usually positioned so that the display thereof is oriented vertically and that the user can look directly at the display. Therefore the portable wireless device which can only tilt about the transverse pivot can be quite inconvenient in use.

Therefore, a portable wireless device having a display that is rotatable about more than one axis is desired. More particularly, a hinge assembly which can connect such a display to a main body of a portable wireless device is desired.

### SUMMARY

An exemplary swivel hinge assembly includes a main body, a pivot mechanism and a swivel mechanism. The swivel mechanism 15 includes a rotatable member, a fixing member, two bearing balls, an elastic piece, and a second pivot shaft. The rotatable member defines two first bearing grooves. The fixing member defines two second bearing grooves corresponding to the first bearing grooves. The bearing balls are disposed between the rotatable member and the fixing member, and are partly received in the second bearing grooves. The elastic piece is mounted on the main body, elastically resisting the fixing member. The second pivot shaft extends through the main body, the elastic piece, the fixing member, and the rotatable member, and is rotatable relative to the elastic piece, the main body, and the fixing member.

Other advantages and novel features will become more apparent from the following detailed description when taken in conjunction with the accompanying drawings.

### BRIEF DESCRIPTION OF THE DRAWINGS

The components in the drawings are not necessarily drawn to scale, the emphasis instead being placed upon clearly illustrating the principles of the swivel hinge assembly and an associated electronic device. Moreover, in the drawings, like reference numerals designate corresponding parts throughout the several views.

FIG. 1 is an exploded, isometric, inverted view of a swivel hinge assembly in accordance with a preferred embodiment of the present invention.

FIG. 2 is similar to FIG. 1, but viewed from another direction.

FIG. 3 is an assembled view of the swivel hinge assembly shown in FIG. 1.

FIG. 4 is a cross-sectional view of the swivel hinge assembly shown in FIG. 3, taken along line IV-IV thereof.

FIG. 5 is an isometric view of a foldable electronic device with the swivel hinge assembly of FIG. 3, showing a display holder of the foldable electronic device rotatable about a first rotational axis and a second rotational axis.

### DETAILED DESCRIPTION OF THE EMBODIMENTS

The present application provides a swivel hinge assembly used in foldable electronic devices that include two components rotatably attached to each other such as mobile phones, personal digital assistants (PDAs), and digital videos (DVs).

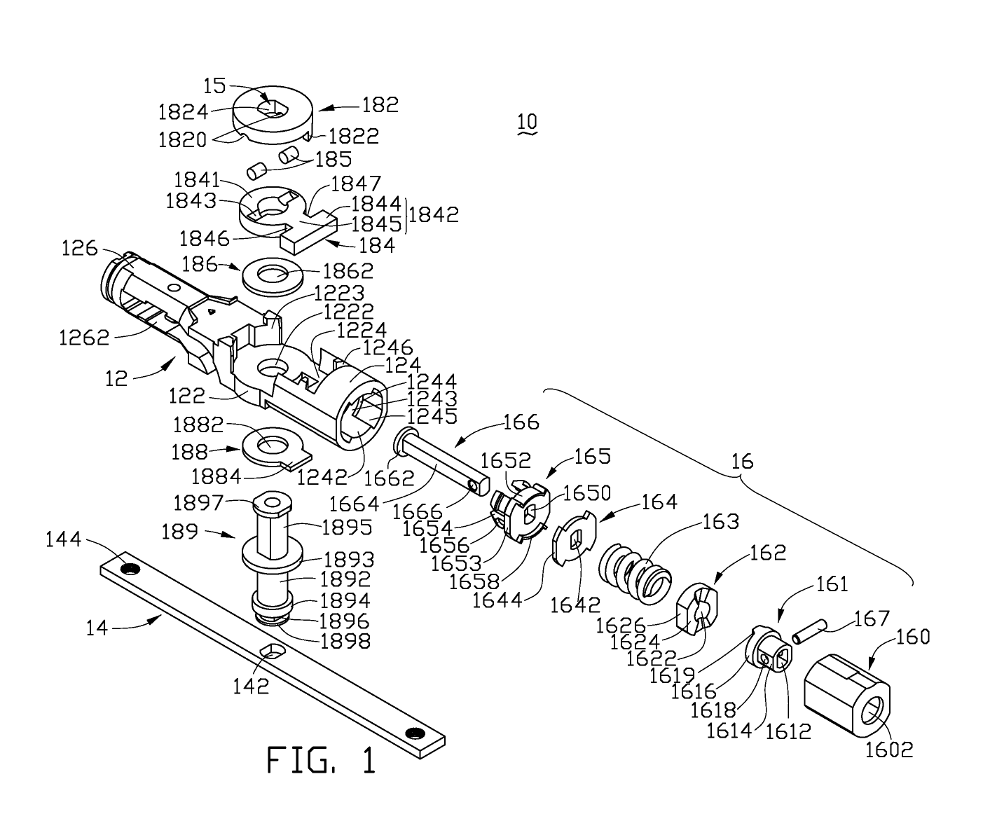

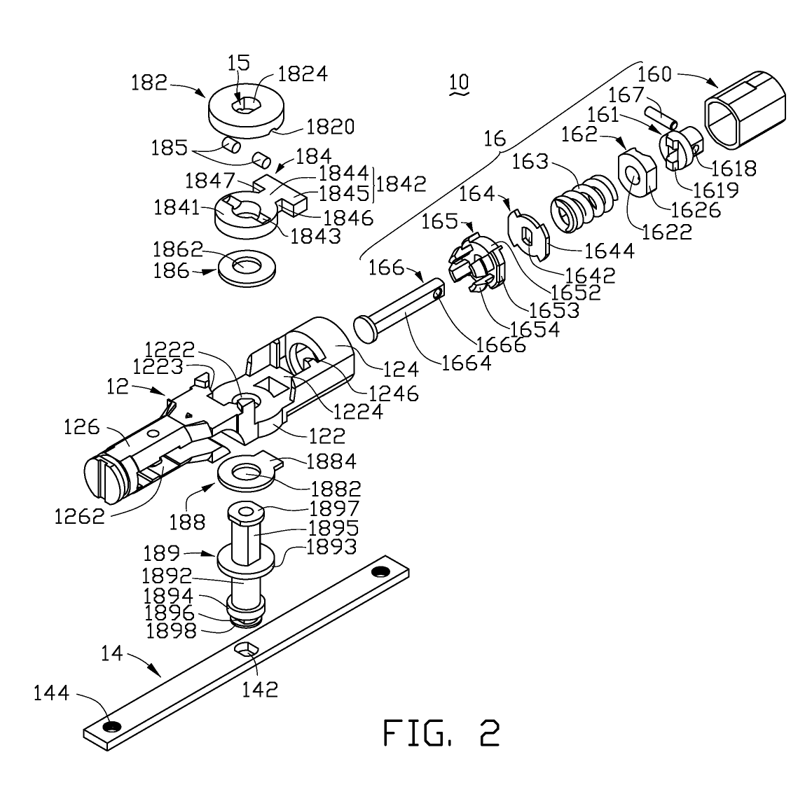

Referring to the drawings in detail, FIG. 1 and FIG. 2 show a swivel hinge assembly 10 of one embodiment of the present invention. The swivel hinge assembly 10 includes a main body 12, a rotatable plate 14, a swivel mechanism 15, and a pivot mechanism 16. The swivel hinge assembly 10 provides rotation about a first rotational axis by virtue of the pivot mechanism 16, and rotation about a second rotational axis perpendicular to the first axis by virtue of the swivel mechanism 15.

The main body 12 includes a swivel 122 with a first arm 124 and a second arm 126 extending from opposite ends of the swivel 122. The main body 12 is integrally formed. A swivel shaft hole 1222 is defined in a center of the swivel 122, with a center axis of the swivel shaft hole 1222 aligned with the second rotational axis. The swivel 122 further forms an arc-shaped sidewall 1223 vertically extending from a part of a rim of the swivel and defines a receiving groove 1224 along another part of the rim of the swivel opposite the arc-shaped sidewall 1223. The receiving groove 1224 is defined by two sidewalls, and has a first opening facing the swivel shaft hole 1222 and a second opening facing to the first arm 124.

In a preferred embodiment, the second arm 126 defines a wiring channel 1262 that is used for wiring two components of a foldable electronic device, and the first arm 124 defines a hinge shaft hole 1243 with an axis of rotation aligned with the first rotational axis. The hinge shaft hole 1243 has a hinge shaft hole wall 1242 having a radius equal to a radius of the hinge shaft hole 1243. The hinge shaft hole wall 1242 defines at least one inner slot 1245 thus forming a step 1244 in the hinge shaft hole 1243. In the preferred embodiment, the hinge shaft hole wall 1242 defines two inner slots 1245. Each inner slot 1245 is arc-shaped, with a radius greater than a radius of the hinge shaft hole 1243. The two inner slots 1245 are symmetrically opposite to each other on the curved hinge shaft hole wall 1242, and respectively communicate with the hinge shaft hole 1243. The first arm 124 further defines at least two hook slots 1246 on opposite sides of the first arm 124. The hook slots 1246 are through holes that communicate from the hinge shaft hole wall 1242 to an exterior surface of the first arm 124.

The rotatable plate 14 is an oblong sheet defines a first latch hole 142 and two mounting holes 144. As seen in FIG. 1 or FIG. 2, the first latch hole 142 has a shape of a circle with two flattened sides. The mounting holes 144 are used for attaching the rotatable plate 14 in the foldable electronic device, and in the preferred embodiment, the mounting holes 144 are threaded. For example, two bolts are provided to screw into the mounting holes 144 so as to fix the rotatable plate 14 to the foldable electronic device. The rotatable plate 14 may instead have another suitable shape. For example, the rotatable plate 14 may instead be a bar having a circular or square cross-section.

The pivot mechanism 16 includes a first pivot shaft 166, a grasping member 165, a tab washer 164, an elastic member 163, a cam follower 162, a cam 161, a pin 167, and a hinge cup 160.

The first pivot shaft 166 includes a cap 1662 and a shaft 1664. The cap 1662 is located at one end of the shaft 1664, and is larger than the shaft 1664. Another end of the shaft 1664 defines a first pinhole 1666. The first pinhole 1666 traverses the shaft 1664, i.e., the first pinhole 1666 has an axis perpendicular to an axis of the shaft 1664. The shaft 1664 is flattened, and has a cross-section having a shape of a circle with two flattened sides. Alternatively, the cross-section of the shaft portion 1664 of the first pivot shaft 166 may be other non-circular shape. For example, the cross-section can be triangular, pentagonal, or hexagonal.

The grasping member 165 defines a first keyed hole 1650 in a center. The first keyed hole 1650 has a shape of a circle with two flattened sides so as to form a cross-section approximately the same as the cross-section of the shaft 1664 of the first pivot shaft 166. The grasping member 165 includes a base 1652. The base 1652 forms two first projections 1653 at a periphery. The first projections 1653 are configured to be engaged in the inner slots 1245 of the main body 12. One end of the base 1652 forms at least two hooks 1654 extending perpendicularly from a periphery of the base 1652. In this embodiment, there are four hooks 1654. Each of the hooks 1654 has a latching surface 1656. Another end of the base 1652 forms two protruding rims 1658. Each of the protruding rims 1658 extends along an edge of the base 1652 in a direction parallel to an axis of the base 1652.

The tab washer 164 is a sheet defining a second keyed hole 1642, and forms a two second projections 1644 at a periphery thereof. The second keyed hole 1642 has a shape of a circle with two flattened sides so as to form a cross-section approximately the same as the cross-section of the shaft 1664 of the first pivot shaft 166. The second projections 1644 are configured to be engaged in the inner slots 1245 of the main body 12. The tab washer 164 is received between the protruding rims 1658 of the grasping member 165. The tab washer 164 is disposed between the elastic member 163 and the grasping member 165 for preventing friction therebetween. Instead, friction is generated between the elastic member 163 and the tab washer 164. Therefore, abrasion of the grasping member 165 is minimal.

In the preferred embodiment, a helical spring is adopted as the elastic member 163. The elastic member 163 is extendable and compressible. In other embodiments, a rubber bar another kind of elastic piece may also be adopted as the elastic member 163. The elastic member 163 is configured to provide an axial force.

The cam follower 162 has a cross-section having a shape of a circle with two flattened sides. The cam follower 162 defines a circular through hole 1622 in a center of the cam follower 162, and a cam surface 1624 at an end. The cam surface 1624 defines a pair of valleys (not labeled). The cam follower 162 has two symmetrical flat surfaces 1626.

A center of the cam 161 defines a third keyed hole 1612. The third keyed hole 1612 has a shape of a circle with two flattened sides so as to form a cross-section approximately the same as the cross-section of the shaft 1664 of the first pivot shaft 166. Alternatively, the cross-section of the shaft 1664 of the first pivot shaft 166 and the first, second, third keyed holes 1650, 1642, 1612 may have other non-circular shapes such as triangular, pentagonal, and hexagonal, so long as the first pivot shaft 166 is non-rotatably extended through the grasping member 165, the tab washer 164, and the cam 161. The cam 161 includes a neck portion 1614, and a cam portion 1616 with a diameter larger than that of the neck portion 1614. The neck portion 1614 defines a transverse second pinhole 1618 therethrough. That is, the second pinhole 1618 has an axis perpendicular to an axis of the cam 161. The cam portion 1616 defines a cam surface 1619, for engaging with the cam surface 1624 of the cam follower 162. The cam portion 1616 forms a pair of peaks (not labeled) for engaging in the valleys of the cam follower 162.

The pin 167 is a cylinder configured to be inserted into the second pinhole 1618 of the cam 161 and the first pinhole 1666 of the first pivot shaft 166. The pin 167 is used for retaining the grasping member 165, the tab washer 164, the elastic member 163, the cam follower 162, and the cam 161 on the first pivot shaft 166.

The hinge cup 160 defines an open end, a polygonal hinge cup cavity, and a hinge cup hole 1602 at a base of the hinge cup 160 communicating with the hinge cup cavity. The hinge cup cavity has at least one flattened section so as to non-rotatably receive the cam follower 162. In the preferred embodiment, the hinge cup cavity has two symmetrical flattened sections that face each other.

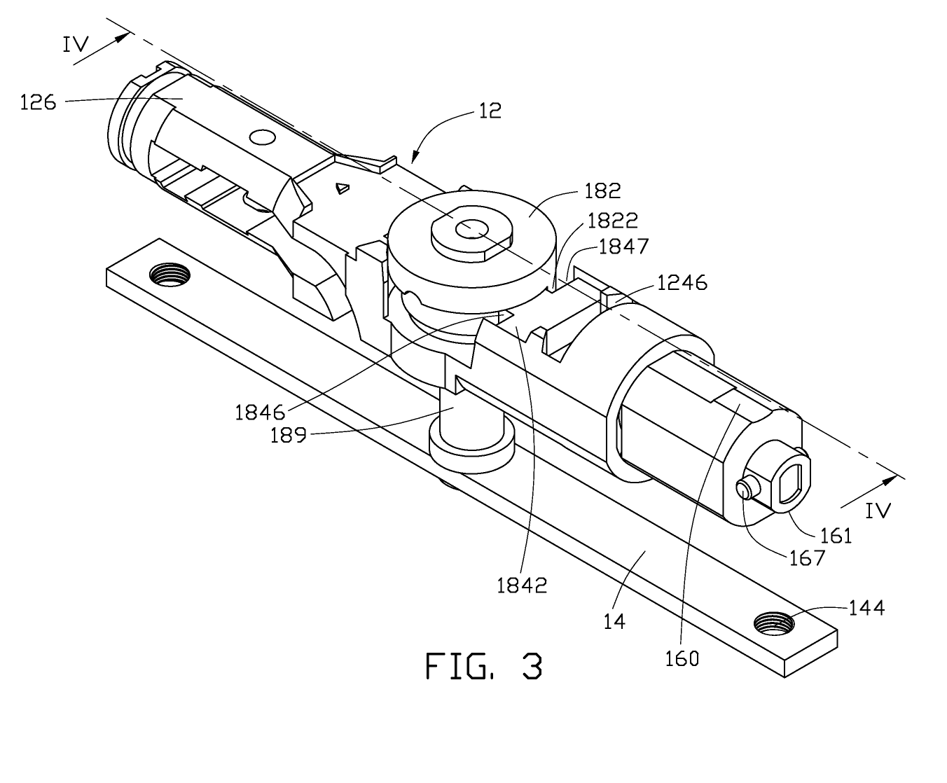

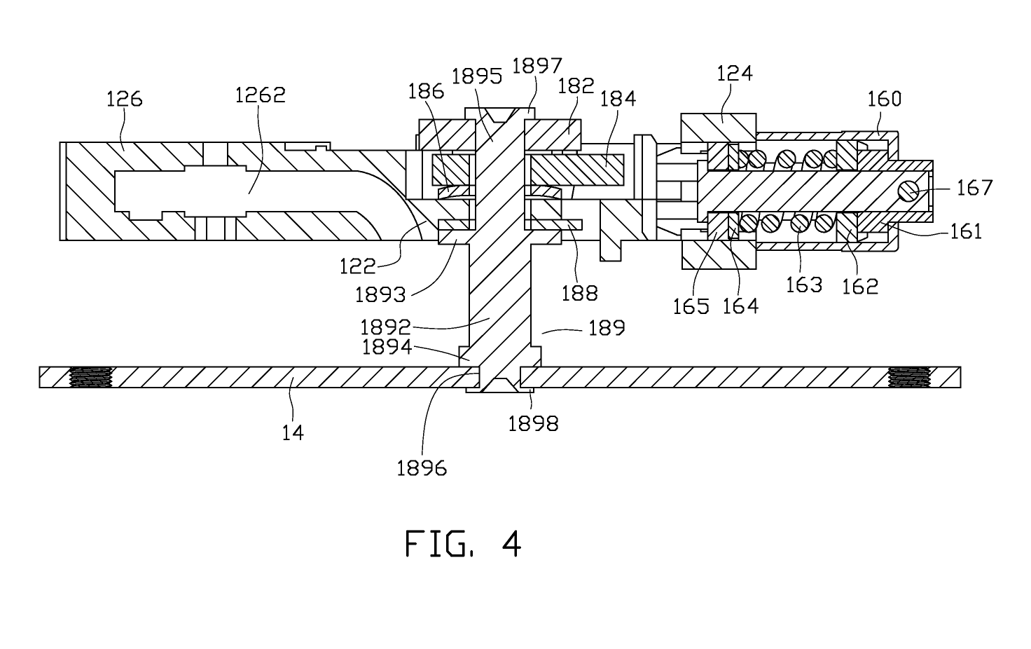

Referring to FIG. 3 and FIG. 4, to assemble the pivot mechanism 16, the shaft 1664 of the first pivot shaft 166 is extended through the first keyed hole 1650 of the grasping member 165, the second keyed hole 1642 of the tab washer 164, the elastic member 163, the through hole 1622 of the cam follower 162, the third keyed hole 1612 of the cam 161, and the hinge cup 160, in that order. The neck portion 1614 of the cam 161 and a part of the first pivot shaft 166 protrudes out of the hinge cup 160 from the hinge cup hole 1602. Then the second pinhole 1618 of the cam 161 and the first pinhole 1666 of the first pivot shaft 166 is inserted with the pin 167 so as to prevent the first pivot shaft 166, the grasping member 165, the tab washer 164, the elastic member 163, the cam follower 162, the cam 161 and the hinge cup 160 from disengaging from each other. The hooks 1654 of the grasping member 165 are pushed inwards so that the hooks 1654 are able to extend through the hinge shaft hole 1243 of the first arm 124, and protrude into the hook slots 1246 of the first arm 124 of the main body 12. Thus, the latching surfaces 1656 of the hooks 1654 of the grasping member 165 hooks an end wall defining the hook slots 1246, and the base 1652 of the grasping member 165 claws the step 1244 of the main body 12, such that the grasping member 165 is fixed to the main body 12, thus connecting the pivot mechanism 16 to the main body 12.

After the pivot mechanism 16 is assembled, the cam follower 162, a portion of the cam follower 161 and a portion of the elastic member 163 are received in the hinge cup cavity of the hinge cup 160, and the tab washer 164, the other portion of the elastic member 163 and a portion of the grasping member 165 are received in the hinge shaft hole 1243 of the first arm 124 of the main body 12. The cam surface 1619 of the cam 161 engages with the cam surface 1624 of the cam follower 162. The two peaks of the cam 161 resist the cam follower 162, with the elastic member 163 being compressed between the tab washer 164 and the cam follower 162. The cam 161 is rotatable relative to the cam follower 162. The cam follower 162 is non-rotatable relative to the hinge cup 160, and the cam 161, the tab washer 164, the grasping member 165 and the first pivot shaft 166 are non-rotatable relative to the main body 12.

In alternative embodiments, the first pinhole 1666 of the first pivot shaft 166, the second pinhole 1618 of the cam 161, the neck portion 1614 of the cam 161, and the pin 167 may be omitted. Instead, for example, the first pivot shaft 166 defines a screw thread and a nut is provided to engage with the screw thread. In another example, an end of the first pivot shaft 166 is riveted by a riveting machine.

The swivel mechanism 15 includes a rotatable member 182, a fixing member 184, two rolling pins 185, an elastic piece 186, a flat washer 188, and a second pivot shaft 189.

The second pivot shaft 189 includes a first shaft portion 1895, a first flange 1893, a second shaft portion 1892, a second flange 1894, and a third shaft portion 1896 arranged in that order. The third shaft portion 1896 has a cross-section approximately the same as a shape of the first latch hole 142 of the rotatable plate 14.

The rotatable member 182 is substantially a ring defining a second latch hole 1824 in a center thereof. The second latch hole 1824 has a shape of a circle with two flattened sides. The rotatable member 182 includes a bottom surface surface defining two first bearing grooves 1820 symmetrically communicating with the second latch hole 1824. Each of the first bearing grooves 1820 is substantially semi-cylindrical. The rotatable member 182 forms a block 1822 at a periphery thereof. Alternatively, the first, and second latch holes 142, 1824, and the first and third shaft portions 1895, 1896 may also have other non-circular shapes such as triangular, pentagonal, and hexagonal, so long as the second pivot shaft 189 is non-rotatably engaged in the first, and second latch holes 142 and 1824.

The fixing member 184 includes a cam portion 1841 and a tab portion 1842 extending from a rim of the cam portion 1841. The cam portion 1841 is substantially a ring defining an axis hole (not labeled) in a center thereof. The fixing member 184 also includes a top surface defining two second bearing grooves 1843 corresponding to the first bearing grooves 1820 of the rotatable member 182. The second bearing grooves 1843 is substantially semi-cylindrical. A depth of the second bearing grooves 1843 is slightly greater than that of the first bearing grooves 1820. The tab portion 1842 is substantially a T-shaped portion extending from a periphery of the cam portion 1841. The tab portion 1842 includes a fixing block 1844 and a limiting block 1845. The limiting block 1845 is configured to connect the fixing block 1844 and the cam portion 1841 so as to form a first limiting surface 1846 and a second limiting surface 1847. The first limiting surface 1846 and the second limiting surface 1847 is configured to correspondingly engage with the block 1822 of the rotatable member 182 at a first utmost and a second utmost position so as to restrict a rotational angle of the swivel hinge assembly 10 about the second rotational axis.

Each of the ball bearings 185 is a cylinder. More than half of each of the ball bearings 185 is received in a corresponding second bearing groove 1843 of the so that the ball bearings 185 can rotate in the second bearing grooves 1843 and the rotatable member 182 can slide on the ball bearings 185.

The elastic piece 186 defines a circular center hole 1862. The elastic piece 186 is disposed between the fixing member 184 and the main body 12 for generating an elastic force when the fixing member 184 is pressed.

The flat washer 188 defines a circular center hole 1882 and forms a tab 1884 at an edge thereof. The flat washer 188 is disposed between the first flange 1893 of the second pivot shaft 189 and the main body 12 for preventing direct friction between them. Instead, friction is generated between the first flange 1893 of the second pivot shaft 189 and the flat washer 188. Therefore, abrasion of the main body 12 is minimal.

Referring to FIG. 3 and FIG. 4 again, in assembly of the swivel mechanism 15, the elastic piece 186 is disposed on the swivel 122 of the main body 12 with the center hole 1862 aligned with the swivel shaft hole 1222. The fixing member 184 is disposed on the elastic piece 186 with the axis hole aligned with the swivel shaft hole 1222. One surface of the cam portion 1841 of the fixing member 184 resists the arc-shaped wall 1223 of the swivel 122 of the main body 12, and the tab portion 1842 is restricted between two sidewalls that bound the corresponding receiving groove 1224 of the main body 12, such that the fixing member 184 is non-rotatable relative to the main body 12. More than half of each of the ball bearings 185 is received in the corresponding second bearing groove 1843 and the rotatable member 182 is disposed above the fixing member 184 with the first bearing groove 1822 engaging with less than half of the corresponding ball bearing 185. Then the first shaft portion 1895 is extended through the circular center hole 1882 of the flat washer 188, the swivel shaft hole 1222 of the main body 12, the center hole 1862 of the elastic piece 186, the axis hole of the fixing member 184, and the second latch hole 1822 of the rotatable member 182, in that order. The third shaft portion 1896 is extended through the first latch hole 142 of the rotatable plate 14. After that, an end of the first shaft portion 1895 and an end of the third shaft portion 1896 are riveted to form a first riveted portion 1897 and a second riveted portion 1898 respectively, thus preventing the rotatable plate 14, the flat washer 188, the main body 12, the elastic piece 186, the fixing member 184, and the rotatable member 182 from disengaging from the second pivot shaft 189. The second pivot shaft 189 is rotatable relative to the main body 12. The rotatable member 182, and the second pivot shaft 189 are non-rotatable relative to the rotatable plate 14.

In alternative embodiments, the first and second riveted portions 1897, 1898 may be omitted. Instead, for example, the second pivot shaft 189 defines two screw threads at two ends thereof, and two nuts are provided to engage with the screw threads. In another example, two pins may be provided, and two pinholes are defined in the second pivot shaft 189. The pins are engaged in the pinholes in a way similar to the way the pin 167 engages in the first pinhole 1666 of the pivot shaft 166 and the second pinhole 1618 of the cam 161.

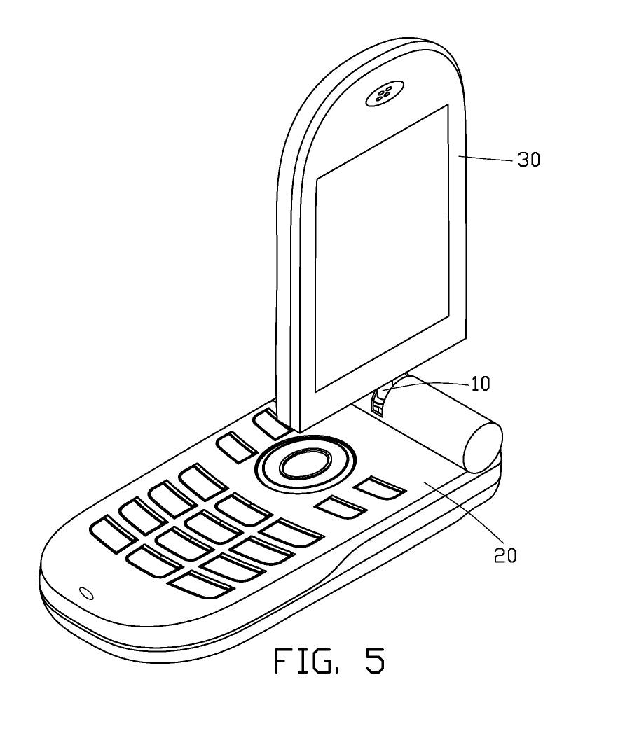

Referring to FIG. 5, the foldable electronic device includes a base body 20, a display holder 30, and the swivel hinge assembly 10 for rotatably connecting the base body 20 and the display holder 30. When the swivel hinge assembly 10 is employed in the foldable electronic device, the hinge cup 160 is non-rotatably connected to the base body 20, and the rotatable plate 14 is fixed to the display holder 30. In a state of the foldable electronic device as shown in FIG. 5, the display holder 30 has been rotated about the first rotational axis and rotated the second rotational axis through respective angles.

In use, when the display holder 30 is manually rotated about the first rotational axis, the cam 161, the tab washer 164, the grasping member 165, the first pivot shaft 166, the main body 12, the rotatable plate 14, and the swivel mechanism 15 rotate together with the display holder 30 relative to the base body 20 and the hinge cup 160, with the cam follower 162 being fixed relative to the base body 20. In a normal starting position of the display holder 30 in relation to the first rotational axis, the peaks of the cam 161 are received in the valleys of the cam follower 162. The normal starting position is typically when the foldable electronic device is folded up and not in use. In such position, the display holder 30 is referred to herein as being in a closed state relative to the base body 20. When the display holder 30 rotates about the first rotational axis, the peaks slide out of the valleys, and drive the elastic member 163 to be compressed further. After rotating through a predetermined angle, the peaks of the cam 161 return into the valleys of the cam follower 162, and thus the elastic member 163 is at rest again. At this position, the display holder 30 stops rotating further, and the display holder 30 is in an open state relative to the base body 20. The cam 161 can be retained at any position relative to the cam follower 162 during the rotating of the display holder 30, because the cam surface 1624 of the cam follower 162 is approximately flat. Therefore, the display holder 30 can be rotated about the first rotational axis and retained in any desired position relative to the base body 20 between the closed state and the open state.

When the display holder 30 is manually rotated about the second rotational axis, the rotatable plate 14, the rotatable member 182 and the second pivot shaft 189 rotate together with the display holder 30 relative to the combination of the base body 20 and the main body 12, with the fixing member 184, the elastic piece 186, the flat washer 188 and the pivotal mechanism 16 being fixed relative to the base body 20. In a normal starting position of the display holder 30 in relation to the second rotational axis, each of the ball bearings 185 has more than half received in a corresponding second bearing groove 1843 of the fixing member 184 and less than half engaged in a corresponding first bearing groove 1822 of the rotatable member 182. When the display holder 30 rotates and reaches a predetermined angle in a first rotating direction, the block 1822 of the rotatable member 182 resists the first limiting surface 1846 of the fixing member 184 to prevent the display holder 30 from rotating further. When the display holder 30 rotates and reaches a predetermined angle in a second rotating direction opposite to the first rotating direction, the block 1822 of the rotatable member 182 resists the second limiting surface 1847 of the fixing member 184 to prevent the display holder 30 from rotating further. Thereby, a rotation angle of the display holder 30 relative to the base body 20 is restricted. When the display holder 30 rotates, the ball bearings 185 slide out from the corresponding first bearing groove 1822 of the rotatable member 182, and more than half still keeps rotating in the corresponding second bearing groove 1843 of the fixing member 184. When the ball bearings 185 slide out from the corresponding first bearing groove 1822 of the rotatable member 182, the rotatable member 182 forces the ball bearings 185 to press the fixing member 184, thus pushes the elastic piece 186 to be deformed. Therefore, friction is generated among the main body 12, the elastic piece 186, and the flat washer 188 when the display holder 30 rotates. This results in a friction moment having a direction reverse to the rotating direction. The friction moment makes the rotation of the display holder 30 about the second rotational axis quite steady, so that the display holder 30 can be stably maintained at any desired position.

It is believed that in many if not most instances, a user desires that the display holder 30 only be rotated about the first rotational axis and not about the second rotational axis. Therefore in the normal starting position of the display holder 30 in relation to the first rotational axis, each of the ball bearings 185 is engaged in the corresponding first bearing groove 1822 of the rotatable member 182 and the corresponding second bearing groove 1843 of the fixing member 184 as regards the second rotational axis. Thus, when the display holder 30 is manually rotated about the first rotational axis away from the starting position, for any movement of the display holder 30 about the second rotational axis to occur, friction forces as among the main body 12, the elastic piece 186, and the flat washer 188 must be overcome. Thereby, when the display holder 30 is rotated up about the first rotational axis as desired, unintentional rotation of the display holder 30 about the second rotational axis is avoided. The ball bearings 185 disposed between the rotatable member 182 and the fixing member 184 may decrease the abrasion between the rotatable member 182 and the fixing member 184 so as to prolong the use life.

In alternative embodiments, the hinge cup 160 may be non-rotatably connected to the display holder 30, and the rotatable plate 14 may be fixed to the base body 20 correspondingly. The rotatable plate 14 may be omitted, and the second pivot shaft 189 may be fixed to the display holder 30 directly. Alternatively, the second pivot shaft 189 may be fixed to the base body 20 directly.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A swivel hinge assembly, comprising:
a main body;
a pivot mechanism connected to the main body and configured to provide the swivel hinge assembly with rotation about a first rotational axis, the pivot mechanism comprising a first pivot shaft aligned with the first rotational axis; and
a swivel mechanism connected to the main body and configured to provide the swivel hinge assembly with rotation about a second rotational axis, the swivel mechanism comprising:
a rotatable member defining two first bearing grooves;
a fixing member defining two second bearing grooves corresponding to the first bearing grooves;
two bearing balls disposed between the rotatable member and the fixing member, and being partly received in the second bearing grooves;
an elastic piece mounted on the main body, elastically resisting the fixing member; and
a second pivot shaft extending through the main body, the elastic piece, the fixing member, and the rotatable member, and the second pivot shaft being rotatable relative to the elastic piece, the main body, and the fixing member about the second rotational axis.

2. The swivel hinge assembly as claimed in claim 1, wherein in a normal starting or an utmostposition in relation to the second rotational axis, more than half of each of the ball bearings is received in a corresponding second bearing groove of the fixing member and less than half of the ball bearings is engaged in a corresponding first bearing groove of the rotatable member.

3. The swivel hinge assembly as claimed in claim 1, wherein the rotatable member is rotatable relative to the main body and is non-rotatable relative to the second pivot shaft about the second rotational axis.

4. The swivel hinge assembly as claimed in claim 1, wherein the rotatable member forms a block at a periphery thereof, the fixing member includes a cam portion and a tab portion extending from a periphery of the cam portion, the tab portion forms a first limiting surface and a second limiting surface for respectively engaging with the block of the rotatable member at a first utmost and a second utmost position so as to restrict a rotational angle of the swivel hinge assembly about the second rotational axis.
The swivel hinge assembly as claimed in claim 4, wherein the rotatable member and the cam portion of the tab portion are both ring-shaped, the tab portion is substantially a T-shaped portion extending from a periphery of the cam portion, the tab portion includes a fixing block and a limiting block, the limiting block is configured for connecting the fixing block and the cam portion so as to form the first limiting surface and the second limiting surface.

6. The swivel hinge assembly as claimed in claim 4, further comprising a rotatable plate, the rotatable plate and the rotatable member each defines a deformed latch hole, the second pivot shaft comprises a first shaft portion, a first flange, a second shaft portion, a second flange, and a third shaft portion arranged in that order, the third shaft portion has a cross-section approximately the same as a shape of the latch hole of the rotatable plate, the first shaft portion has a cross-section approximately the same as a shape of the latch hole of the rotatable member, such that the first shaft portion of the second pivot shaft is non-rotatably extended in the latch hole of the rotatable member, the third shaft portion is non-rotatably extended in the latch hole of the rotatable plate.

7. The swivel hinge assembly as claimed in claim 6, wherein the swivel mechanism further comprises a flat washer disposed between the main body and the first flange of the second pivot shaft, the flat washer forms a tab at an edge for preventing the flat washer from rotating relative to the main body, the flat washer defines a center hole for the second pivot shaft rotatably extending therethrough.

8. The swivel hinge assembly as claimed in claim 4, wherein the main body comprises a swivel, the swivel defines a circular swivel shaft hole, and defines a receiving groove adjacent to one side of the circular swivel shaft hole, and forms an arc-shaped sidewall adjacent to an opposite side of the swivel shaft hole, the receiving groove is defined by two sidewalls, the tab portion of the fixing member is received in the receiving groove, one end of the cam portion of the fixing member resists the arc-shaped wall.

9. The swivel hinge assembly as claimed in claim 8, wherein the main body further comprises a first arm and a second arm extending from opposite ends of the swivel, the first arm defines a hinge shaft hole, the hinge shaft hole has a hinge shaft hole wall and defines at least one inner slot, thereby forming a step in the hinge shaft hole, the first arm further defines two hook slots communicating from the hinge shaft hole wall to an exterior surface of the first arm, the second arm defines a wiring channel for receiving wires.

10. The swivel hinge assembly as claimed in claim 9, wherein the pivot mechanism further comprises a hinge cup, a cam, a cam follower, an elastic member, and a grasping member, the first pivot shaft is extended through the grasping member, the elastic member, the cam follower, the cam, and the hinge cup, the cam is rotatably engaged with the cam follower, the cam follower is non-rotatable relative to the hinge cup, the cam, the tab washer, the grasping member and the second pivot shaft are non-rotatable relative to the main body.

11. The swivel hinge assembly as claimed in claim 10, wherein the cam and the cam follower each defines a cam surface for engaging with each other, one of the cam and the cam follower forms a pair of peaks on the cam surface, the other one of the cam and the cam follower defines a pair of valleys for engaging with or disengaging from the peaks.

12. The swivel hinge assembly as claimed in claim 1, wherein the cam comprises a cam portion and a neck portion, the cam surface is defined at one end of the cam portion and the neck portion is opposite to the cam surface, the neck portion and the first pivot shaft each defines a pinhole, the pivot mechanism further comprises a pin for being inserted into the pinholes so as to prevent the first pivot shaft, the grasping member, the tab washer, the elastic member, the cam follower, the cam and the hinge cup from disengaging from each other.

13. The swivel hinge assembly as claimed in claim 10, wherein the hinge cup defines an open end, a hinge cup cavity and a hinge cup hole at a base of the hinge cup communicating with the hinge cup cavity, the hinge cup cavity has at least one flattened section so as to non-rotatably receive the cam follower, the pivotal mechanism further comprises a tab washer disposed between the elastic member and the grasping member, the first pivot shaft comprises a cap and a deformed shaft, the cam, the grasping member and the tab washer each defines a keyed hole having a shape approximately the same as a cross-section of the deformed shaft for non-rotatably surrounding the first pivot shaft.

14. The swivel hinge assembly as claimed in claim 13, wherein the grasping member includes a base, the base and the tab washer each forms two projections at a periphery thereof so as to engaged in the inner slots of the main body, and one end of the base forms at least two hooks having a latching surface, the hooks can be bend inwards and run through the hinge shaft hole of the first arm of the main body and protrude into the hook slots, the latching surfaces of the hooks claw an end surface for defining the hook slots, and the base of the grasping member claws the step of the main body, an opposite end of the base forms two protruding rims, the tab washer is received between the protruding rims.

15. An electrical device comprising:
a first body;
a second body; and
a swivel hinge assembly rotatably connecting the first body and the second body and providing biaxial rotation of the first and second bodies relative to each other, the swivel hinge assembly comprising:
a main body;
a pivot mechanism connected to the main body and configured to provide the swivel hinge assembly with rotation about a first rotational axis, the pivot mechanism comprising a hinge cup rotatable relative to the main body and fixed to one of the first body and the second body; and
a swivel mechanism configured to provide the swivel hinge assembly with rotation about a second rotational axis, the swivel mechanism comprising:
a rotatable member defining two first bearing grooves;
a fixing member defining two second bearing grooves corresponding to the first bearing grooves;
two bearing balls disposed between the rotatable member and the fixing member, and being partly received in the second bearing grooves;
an elastic piece mounted on the main body, elastically resisting the fixing member; and a second pivot shaft extending through the main body, the elastic piece, the fixing member, and the rotatable member, and being rotatable relative to the elastic piece, the main body, and the fixing member about the second rotational axis.

16. The electrical device as claimed in claim 15, wherein the rotatable member forms a block at a periphery thereof, the fixing member includes a cam portion and a tab portion extending from a periphery of the cam portion, the tab portion forms a first limiting surface and a second limiting surface for respectively engaging with the block of the rotatable member at a first utmost and a second utmost position so as to restrict a rotational angle of the swivel hinge assembly about the second rotational axis.

17. The electrical device as claimed in claim 16, wherein the rotatable member and the cam portion of the tab portion are both ring-shaped, the tab portion is substantially a T-shaped portion extending from a periphery of the cam portion, the tab portion includes a fixing block and a limiting block, the limiting block is configured for connecting the fixing block and the cam portion so as to form the first limiting surface and the second limiting surface.

18. The electrical device as claimed in claim 16, further comprising a rotatable plate, the rotatable plate, and the rotatable member each defines a deformed latch hole, the second pivot shaft comprises a first shaft portion, a first flange, a second shaft portion, a second flange, and a third shaft portion arranged in that order, the third shaft portion has a cross-section approximately the same as a shape of the latch hole of the rotatable plate, the first shaft portion has a cross-section approximately the same as a shape of the latch hole of the rotatable member, such that the first shaft portion of the second pivot shaft is non-rotatably extended in the latch hole of the rotatable member, the third shaft portion is non-rotatably extended in the latch hole of the rotatable plate.

19. The electrical device as claimed in claim 18, wherein the swivel mechanism further comprises a flat washer disposed between the main body and the first flange of the second pivot shaft, the flat washer forms a tab at an edge for preventing the flat washer from rotating relative to the main body, the flat washer defines a center hole for the second pivot shaft rotatably extending therethrough.

20. The electrical device as claimed in claim 15, wherein the pivot mechanism further comprises a hinge cup, a cam, a cam follower, an elastic member, and a grasping member, the first pivot shaft is extended through the grasping member, the elastic member, the cam follower, the cam, and the hinge cup, the cam is rotatably engaged with the cam follower, the cam follower is non-rotatable relative to the hinge cup, the cam, the tab washer, the grasping member and the second pivot shaft are non-rotatable relative to the main body.
